(19) United States
(12) Patent Application Publication
(10) Pub. No.: US 2004/0142535 A1
(43) Pub. Date: Jul. 22, 2004

(54) Method for forming metal-insulator-metal capacitor of semiconductor device

(76) Inventor: Yi Sun Chung, Chungcheongbuk-do (KR)

Correspondence Address: LADAS & PARRY, 224 SOUTH MICHIGAN AVENUE, SUITE 1200, CHICAGO, IL, 60604, US

(21) Appl. No.: 10/738,398

(22) Filed: Dec. 17, 2003

(30) Foreign Application Priority Data
Jan. 21, 2003 (KR) 2003-3951

(51) Int. Cl. H01L 21/20

(52) U.S. Cl. 438/396; 438/393

(57) ABSTRACT

Disclosed is a method for forming an MIM capacitor of a semiconductor device, in which a lower electrode is utilized as a dielectric layer of a capacitor. The method comprises the steps of forming a via at a first insulating layer in order to expose a lower metal wire, forming a first barrier layer at a surface of the first insulating layer including the via, forming a metal layer on the first insulating layer in which the first barrier layer is formed, forming a capacitor lower electrode layer after forming a second barrier layer and a third barrier layer on the metal layer, forming a dielectric layer by oxidizing the capacitor lower electrode layer, forming a capacitor upper electrode layer on the dielectric layer, and patterning the capacitor upper electrode layer, the dielectric layer, and the capacitor lower electrode layer, thereby forming the capacitor. By forming the capacitor through oxidizing the lower electrode, it is not required to provide deposition equipment for depositing a dielectric layer having high dielectric constant, so manufacturing cost for the semiconductor device is saved. Since a chamber capable of forming an oxygen atmosphere is formed in lower electrode deposition equipment, the process is performed in one equipment in-situ, so that a process time remarkably reduced. Also, contamination owing to the substrate movement is minimized, because the process is carried out in one piece of equipment.

### BACKGROUND OF THE INVENTION

1. Field of the Invention

The present invention relates to a method for forming an MIM (hereinafter, referred to as “MIM”) capacitor of a semiconductor device, and more particularly to a method for forming an MIM capacitor of a semiconductor device, which can remove a depositing step of a dielectric layer by oxidizing a lower electrode in order to utilize an oxidized lower electrode as the dielectric layer of the MIM capacitor.

2. Description of the Prior Art

An analog capacitor applied in a CMOS IC Logic device requiring high precision is a main factor in advanced analog MOS technology, particularly in an A/D converter or a switching capacitor filter field. Structures for an analog capacitor include a Polysilicon-Insulator-Polysilicon (PIP), Polysilicon-Insulator-Metal (PIM), Metal-Insulator-Polysilicon (MIP), and Metal-Insulator-Metal (MIM) structures.

The MIM structure has a low series resistance, so the MIM structure can make a capacitor having a high capacitance. Particularly, because the MIM structure has merits of a low thermal budget and Vcc, the MIM structure is used as a typical structure of the analog capacitor.

This MIM capacitor is variously applied to a Radio Frequency circuit, an analog IC, a decoupling capacitor of a high power MPU, and a DRAM cell in a semiconductor circuit.

Hereinafter, a conventional method for forming a MIM capacitor of a semiconductor device will be explained with reference to FIGS. 1 to 5.

According to the conventional method for forming the MIM capacitor of the semiconductor device, as shown in FIG. 1, a via 20 is formed in an insulating layer 15 such that a lower metal wire 10 is exposed by a dual damascene process. Then, a barrier metal 25 is formed. At this time, Ti is used as the barrier metal 25.

Next, as shown in FIG. 2, Cu 30 is deposited on the barrier metal 25 in order to use Cu 30 as a lower electrode.

Thereafter, as shown in FIG. 3, after performing a CMP (Chemical Mechanical Polishing) process, Si₃N₄ or SiC is deposited. Then, after performing a photo process and an etching process, a barrier metal layer 40 is formed.

Next, as shown in FIG. 4, a high dielectric layer 45 and an upper electrode layer 50 are formed on the barrier metal layer 40.

Next, as shown in FIG. 5, after the capacitor structure including a Cu layer 30a, a high dielectric layer 45a and an upper electrode layer 50a has been formed trough a photo process, a metal wire 55 is formed through a next process.

However, the conventional method for forming the MIM capacitor of the semiconductor device has problems as follows.

According to the conventional method, Ta₂O₅, Hf₂O₅ and Zr₂O₅ having a high dielectric constant are deposited through CVD, Sputtering and ALD processes as a dielectric layer of the capacitor. Materials having a high dielectric constant have a porous characteristic. Therefore, after a deposition process has been finished, a post treatment process, such as a plasma treatment or an annealing treatment, is absolutely necessary. Accordingly, manufacturing cost is increased. In addition, because many processing steps are required, much time is required.

### SUMMARY OF THE INVENTION

Accordingly, the present invention has been make to solve the above-mentioned problems occurring in the prior art, and an object of the present invention is to provide a method for forming an MIM capacitor of a semiconductor device, in which an insulating layer is formed through processing a lower electrode so that a process for forming a dielectric layer is not required, thereby simplifying the process.

In order to accomplish this object, there is provided a method for forming an MIM capacitor of a semiconductor device, the method comprising the steps of: method for forming an MIM capacitor of a semiconductor □device, the method comprising the steps of: forming a via at a first insulating layer in order to expose a lower metal wire; forming a first barrier layer at a surface of the first insulating layer including the via; forming a metal layer on the first insulating layer in which the first barrier layer is formed; forming a capacitor lower electrode layer after forming a second barrier layer and a third barrier layer on the metal layer; forming a dielectric layer by oxidizing the capacitor lower electrode layer; forming a capacitor upper electrode layer on the dielectric layer; and patterning the capacitor upper electrode layer, the dielectric layer, and the capacitor lower electrode layer, thereby forming the capacitor.

According to a preferred embodiment of the present invention, the insulating layer is formed through processing the capacitor lower electrode, so a process for forming a dielectric layer is not required.

### BRIEF DESCRIPTION OF THE DRAWINGS

The above object, features and advantages of the present invention will be more apparent from the following detailed description taken in conjunction with the accompanying drawings, in which:

FIGS. 1 to 5 are sectional views to explain a conventional method for forming an MIM capacitor of a semiconductor device; and

FIGS. 6 to 12 are sectional views to explain a method for forming an MIM capacitor of a semiconductor device according to one embodiment of the present invention.

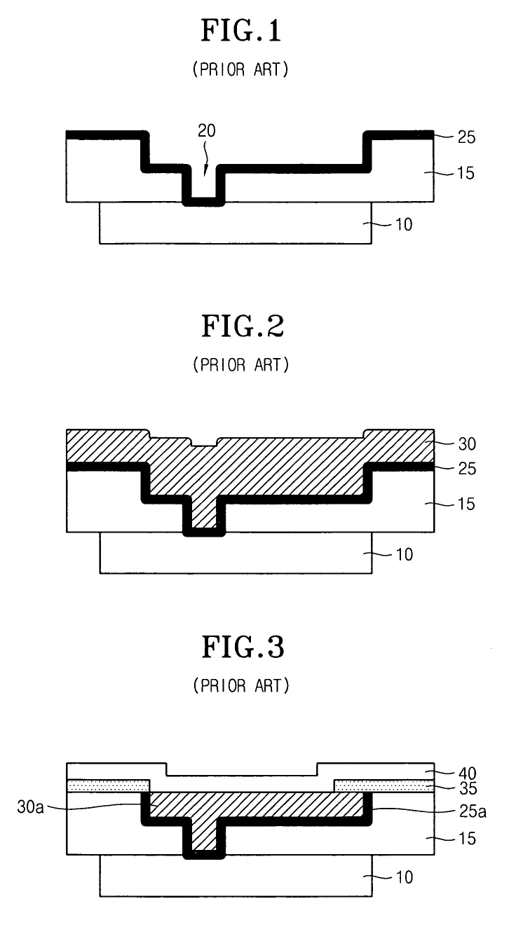

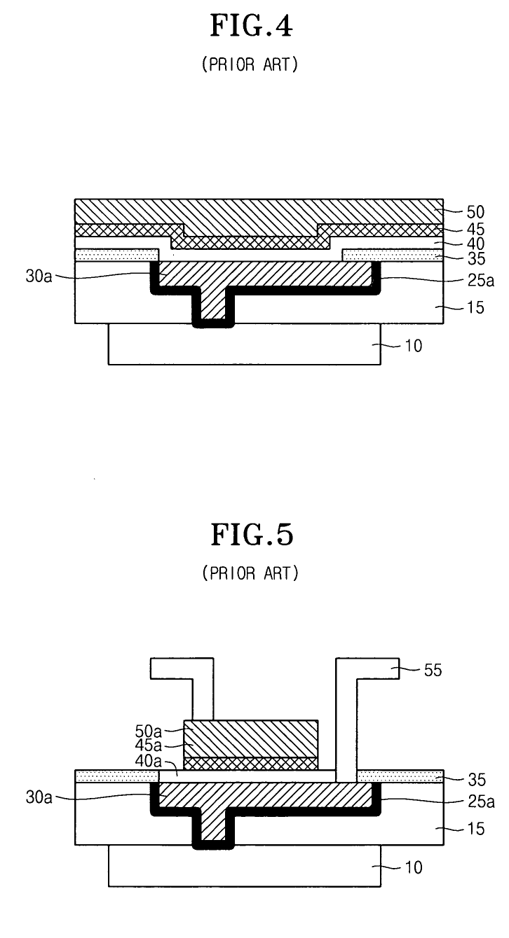

### DETAILED DESCRIPTION OF THE PREFERRED EMBODIMENTS

Hereinafter, a method for forming an MIM capacitor of a semiconductor device according to the present invention will be described with reference to the accompanying drawings.

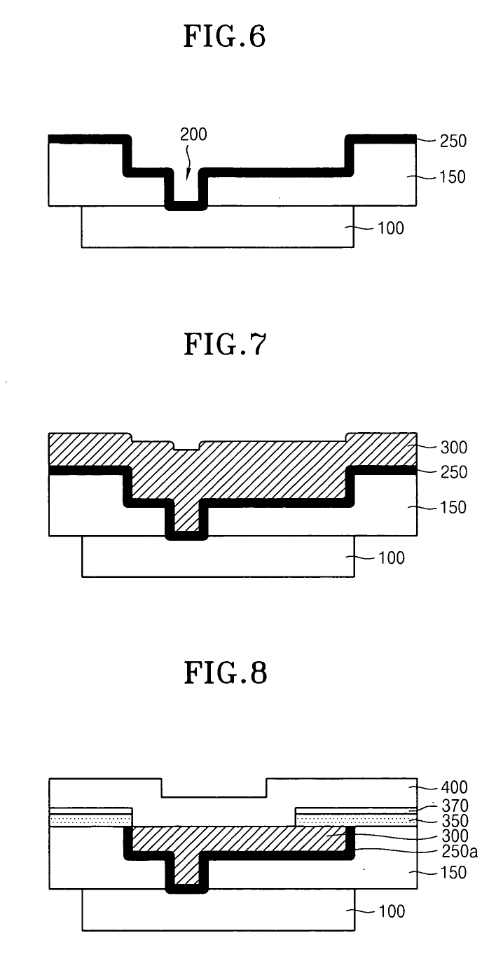

FIGS. 6 to 12 are sectional views to explain a method for forming an MIM capacitor of a semiconductor device in accordance with the present invention.

According to the method for forming the MIM capacitor of the semiconductor device, as shown in FIG. 6, a via 200 is formed at a first insulating layer 150 so as to expose a lower metal wire 100. Thereafter, TiN, TaN and Ta are deposited on the first insulating layer 150 to form a first barrier layer 250.

Sequentially, as shown in FIG. 7, Cu is deposited on the first insulating layer 150 formed with the first barrier layer 250, thereby forming a metal layer 300. After that, the metal layer 300 is planarized through a CMP process.

Next, as shown in FIG. 8, after forming a second barrier layer 350 and a third barrier layer 370 on the metal layer 300, a lower electrode layer-400 of a capacitor is formed.

The lower electrode layer 400 of the capacitor is formed using metal capable of forming a layer having high dielectric constant. The metal is one selected from the group consisting of TaN, Ta, Ti, TiN and Ru.

Also, the metal has an amorphous structure formed by performing one of CVD, ALD and sputtering processes. TaN, Ta, Ti, TiN and Ru are deposited in an amorphous state, and have a superior oxidation characteristic. Therefore, TaN can be used as a lower electrode layer of the capacitor, and can be used as a dielectric layer of the capacitor by oxidizing TaN.

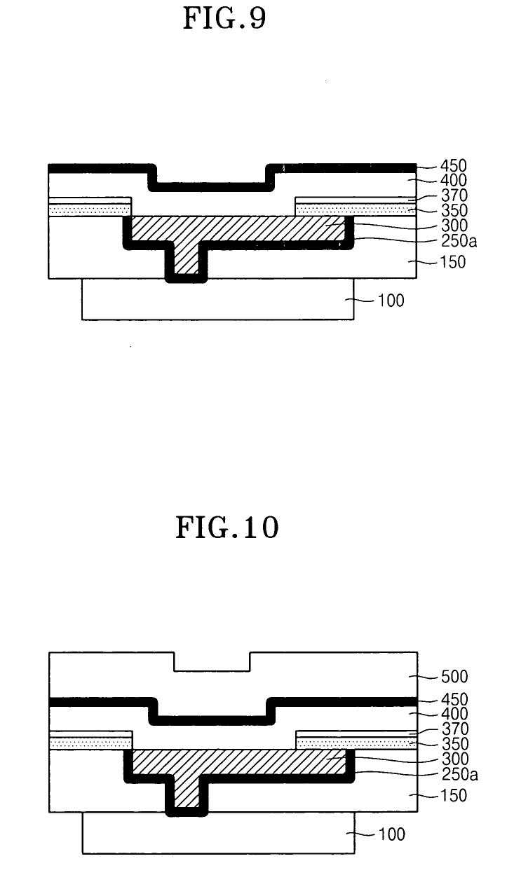

Thereafter, as shown in FIG. 9, a dielectric layer 450 is formed by oxidizing the lower electrode layer 400 of the capacitor about 10 Å to 800 Å using an oxidation process, which is one selected from the group consisting of an oxygen plasma treatment process, an ozone plasma treatment process, and an oxygen annealing treatment process.

The oxidization process is performed at the temperature below 500° C. Also, the oxygen plasma treatment process is performed with a power of 100 W to 30,000 W, preferably 200 W to 30,000 W.

Next, as shown in FIG. 10, an upper electrode layer 500 of the capacitor is formed on the dielectric layer 450 through depositing one selected from the group consisting of TaN, Ta, Ti, TiN and Ru.

At this time, it is preferable that a process for forming the lower electrode layer 400 of the capacitor, the dielectric layer 450 and the upper electrode layer 500 of the capacitor is performed in same equipment in-situ in order to minimize a process time and to reduce contamination owing to a movement of a substrate.

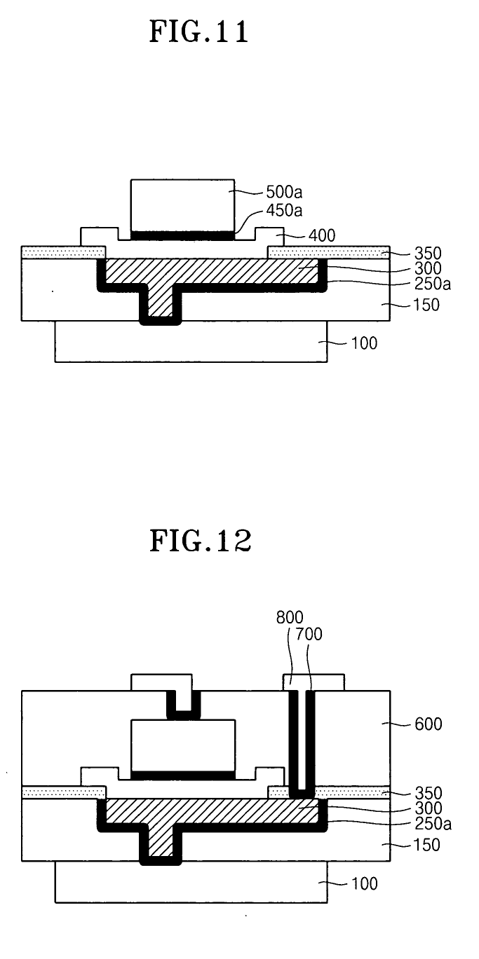

Thereafter, as shown in FIG. 11, the upper electrode layer 500 of the capacitor, the dielectric layer 450, and the lower electrode layer 400 of the capacitor are patterned to form a capacitor structure including an upper electrode 500a, a dielectric layer 450a and a lower electrode 400a.

Next, as shown in FIG. 12, various processes including a second insulating layer depositing process, a photo process, an etching process, a barrier metal depositing process, a Cu depositing process, and a Cu wire forming process, an annealing process and a CMP process are carried out, thereby forming the semiconductor device.

As explained above, the method for forming the MIM capacitor of the semiconductor device according to the present invention has an effect as follows.

According to the present invention, when the capacitor is formed by oxidizing the lower electrode, it is not required to provide deposition equipment for depositing a dielectric layer having high dielectric constant, so manufacturing cost for the semiconductor device can be saved. In addition, since a chamber capable of forming an oxygen atmosphere is formed in lower electrode deposition equipment, the process is performed in one equipment in-situ, so that a process time remarkably reduced. Also, contamination owing to the substrate movement can be minimized, because the process is carried out in one piece of equipment.

Although preferred embodiments of the present invention have been described for illustrative purposes, those skilled in the art will appreciate that various modifications, additions and substitutions are possible, without departing from the scope and spirit of the invention as disclosed in the accompanying claims.

What is claimed is:

1. A method for forming an MIM capacitor of a semiconductor □device, the method comprising the steps of:
i) forming a via at a first insulating layer in order to expose a lower metal wire;
ii) forming a first barrier layer at a surface of the first insulating layer including the via;
iii) forming a metal layer on the first insulating layer in which the first barrier layer is formed;
iv) forming a capacitor lower electrode layer after forming a second barrier layer and a third barrier layer on the metal layer;
v) forming a dielectric layer by oxidizing the capacitor lower electrode layer;
vi) forming a capacitor upper electrode layer on the dielectric layer; and
vii) patterning the capacitor upper electrode layer, the dielectric layer, and the capacitor lower electrode layer, thereby forming the capacitor.

2. The method according to claim 1, wherein the capacitor lower electrode layer is formed using a metal capable of forming a layer having high dielectric constant.

3. The method according to claim 2, wherein the metal is formed with an amorphous structure by using one process selected from the group consisting of CVD, ALD and sputtering processes.

4. The method according to claim 2 or 3, wherein the metal is one selected from the group consisting of TaN, Ta, Ti, TiN and Ru.

5. The method according to claim 2, wherein, in step v), the capacitor lower electrode layer is oxidized by a thickness about 10 Å to 800 Å.

6. The method according to claim 5, wherein the capacitor lower electrode layer is oxidized by using one process selected from the group consisting of an oxygen plasma treatment process, an ozone plasma treatment process, and an oxygen annealing treatment process.

7. The method according to claim 6, wherein the oxygen plasma treatment process is carried out with a power of 100 W to 30,000 W.

8 The method according to claim 6, wherein the oxygen plasma treatment process is carried out with a power of 200 W to 30,000 W.

9. The method according to claim 1, wherein the capacitor upper electrode layer is formed by using one selected from the group consisting of TaN, Ta, Ti, TiN and Ru.

10. The method according to claim 1, wherein the capacitor lower electrode layer, the dielectric layer, and the upper electrode are formed in-situ.
